(19) United States
(12) Patent Application Publication
(10) Pub. No.: US 2020/0243306 A1
(43) Pub. Date: Jul. 30, 2020

(54) OPENING AND SHUTTING DEVICE AND SUBSTRATE PROCESSING APPARATUS INCLUDING THE SAME

(71) Applicant: KCTECH CO.,LTD., Gyeonggi-do (KR)

(72) Inventor: Yong Ki HAN, Gyeonggi-do (KR)

(73) Assignee: KCTECH CO.,LTD., Gyeonggi-do (KR)

(21) Appl. No.: 16/750,317

(22) Filed: Jan. 23, 2020

(30) Foreign Application Priority Data
Jan. 25, 2019 (KR) 10-2019-0010081

(51) Int. Cl. H01J 37/32; H01L 21/67; E05F 15/00

(52) U.S. Cl. CPC H01J 37/32513; H01L 21/67069; E05Y 2900/60; H01J 2237/334; E05F 15/00

(57) ABSTRACT

Disclosed are an opening and shutting device and a substrate processing apparatus including the same. A device for opening and closing an entrance through which a substrate is carried into and out of a processing chamber includes an opening and shutting part that is disposed between the entrance and the processing chamber and that opens and closes the entrance while rotating so as to be brought into close contact with the entrance.

### CROSS-REFERENCE TO RELATED APPLICATION(S)

This application claims the benefit of Korean Patent Application No. 10-2019-0010081, filed on Jan. 25, 2019, in the Korean Intellectual Property Office, the disclosure of which is incorporated herein by reference.

### BACKGROUND

### 1. Field of the Invention

Example embodiments relate to an apparatus for processing a semiconductor substrate.

### 2. Description of the Related Art

In general, etching apparatuses are mainly classified into a wet etching apparatus using a wet chemical and a dry etching apparatus using plasma. The dry etching apparatus generates ionized plasma with very excellent reactivity by supplying a neutral reactant gas between two electrodes and subjecting the neutral reactant gas to an electric field. An etching process of removing a predetermined film on the surface of a substrate is performed by applying the generated plasma to the substrate to be processed.

The dry etching apparatus generally includes a processing chamber for performing a predetermined process on a substrate using plasma, a transfer chamber for carrying the substrate into or out of the processing chamber, and a load-lock chamber for storing the substrate.

In the dry etching apparatus, the processing chamber has, on one side thereof, an entrance for entrance or exit of the substrate. The entrance is a passage through which the substrate is carried into or out of the processing chamber.

The interior of the processing chamber has to be isolated and sealed from the outside to generate plasma and maintain a process atmosphere.

The dry etching apparatus in the related art is equipped with a gate valve to open and close the entrance, and the gate valve is installed on the exterior of the processing chamber. The gate valve opens and closes, outside the processing chamber, the entrance, and therefore a space with a predetermined volume is formed between the gate valve and the processing chamber when the gate valve is closed. That is, the portion having the entrance formed therein has a larger volume than the other portion. Due to this, when plasma is generated in the processing chamber, non-uniformity of plasma density is caused by the space, and the substrate fails to be uniformly processed.

The above information presented as background information was held or acquired by the inventor in the process of deriving the invention, and cannot be necessarily regarded as well-known technology disclosed to general public before the application of the invention.

### SUMMARY

An aspect provides a substrate processing apparatus including an opening and shutting device that effectively keeps the substrate processing apparatus sealed and that is easy to open and close.

The problems to be solved by the invention are not limited to the aforementioned problems, and any other problems not mentioned herein will be clearly understood from the following description by those skilled in the art to which the invention pertains.

According to an aspect, there is provided a device for opening and closing an entrance through which a substrate is carried into and out of a processing chamber, the device including an opening and shutting part that is disposed between the entrance and the processing chamber and that opens and closes the entrance while rotating so as to be brought into close contact with the entrance.

According to another aspect, there is provided a substrate processing apparatus including a housing including a processing chamber for substrate processing and having, on one side thereof, an entrance through which a substrate is carried into and out of the processing chamber, an opening and shutting part that is provided in the housing so as to be located between the processing chamber and the entrance and that selectively opens and closes the entrance while rotating, and a drive part that is connected with the opening and shutting part and that rotates the opening and shutting part.

Additional aspects of example embodiments will be set forth in part in the description which follows and, in part, will be apparent from the description, or may be learned by practice of the disclosure.

### BRIEF DESCRIPTION OF THE DRAWINGS

The accompanying drawings illustrate an example embodiment of the invention and together with the foregoing disclosure, serve to provide further understanding of the technical spirit of the invention, and thus, the invention is not to be construed as being limited to the drawings.

FIG. 1 is a perspective view of a substrate processing apparatus according to an embodiment;

FIG. 2 is a cross-sectional view of an opening and shutting device according to an embodiment;

FIG. 3 is a cross-sectional view of the opening and shutting device according to an embodiment;

FIG. 4 is a perspective view of an opening and shutting part according to an embodiment;

FIG. 5 is a cross-sectional view of an opening and shutting device according to an embodiment; and

FIG. 6 is a cross-sectional view of an opening and shutting device according to an embodiment.

### DETAILED DESCRIPTION

Hereinafter, embodiments of the invention will be described in detail with reference to the exemplary drawings. In adding the reference numerals to the components of each drawing, it should be noted that the identical or equivalent component is designated by the identical numeral even when they are displayed on other drawings. Further, in describing the embodiment of the invention, a detailed description of well-known features or functions will be ruled out in order not to unnecessarily obscure the gist of the invention.

In describing the components of the embodiment according to the invention, terms such as first, second, “A”, “B”, (a), (b), and the like may be used. These terms are merely intended to distinguish one component from another component, and the terms do not limit the nature, sequence or order of the components. When a component is described as “connected”, “coupled”, or “linked” to another component, this may mean the components are not only directly “connected”, “coupled”, or “linked”, but also are indirectly “connected”, “coupled”, or “linked” via a third component.

A component, which has the same common function as a component included in any one example embodiment, will be described using the same name in other example embodiments. Unless otherwise stated, the description set forth in any one example embodiment may be applicable to other example embodiments, and a detailed description will be omitted in an overlapping range.

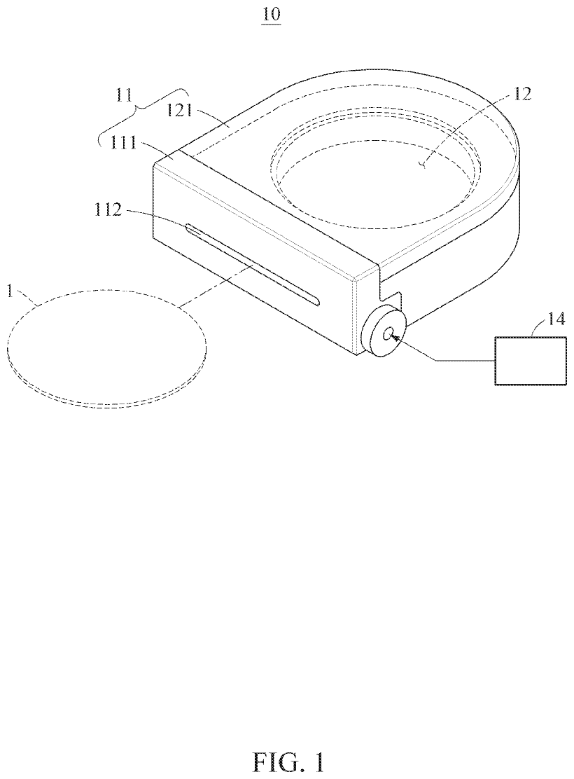

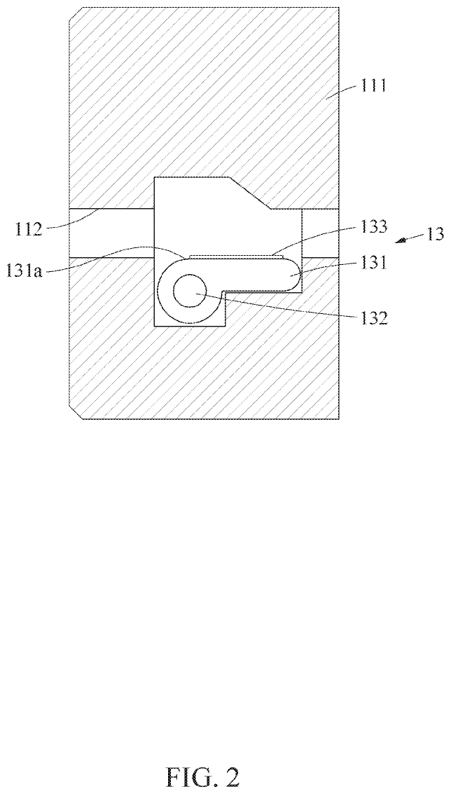

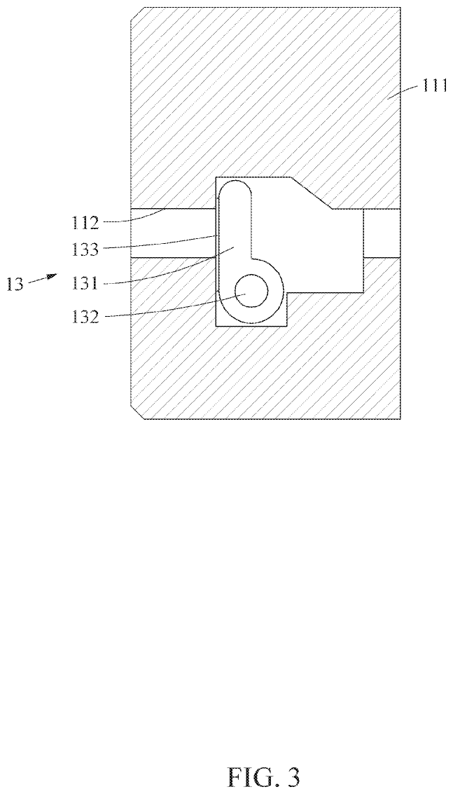

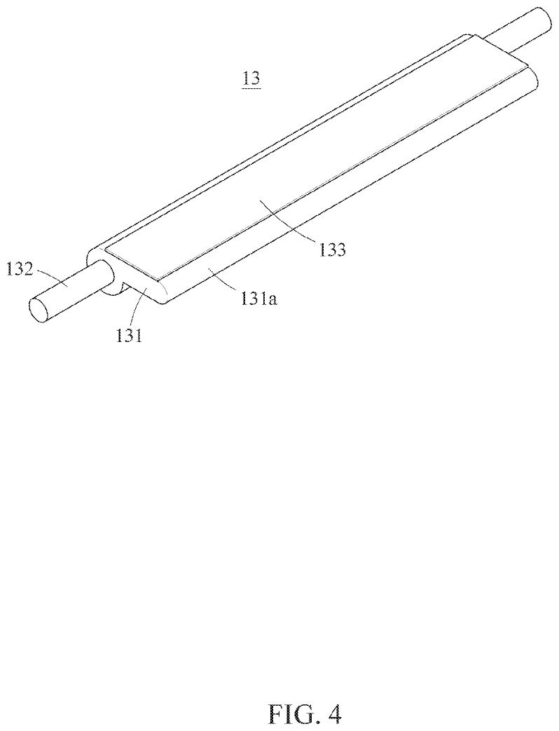

FIG. 1 is a perspective view of a substrate processing apparatus according to an embodiment. FIG. 2 is a cross-sectional view of an opening and shutting device according to an embodiment. FIG. 3 is a cross-sectional view of the opening and shutting device according to an embodiment. FIG. 4 is a perspective view of an opening and shutting part according to an embodiment.

Referring to FIGS. 1 to 4, the substrate processing apparatus 10 according to an embodiment may be used to perform substrate processing. The substrate processing apparatus 10 may provide a specific environment for the substrate processing, for example, processing environments such as high temperature or high pressure, chemical processing, and the like. The substrate processing apparatus 10 may stably seal the interior of a chamber while simply carrying a substrate into or out of the chamber.

A substrate 1 that is processed in the substrate processing apparatus 10 may be a silicon wafer that is a semiconductor substrate. However, the invention is not limited thereto, and the substrate 1 may be a glass substrate for a flat panel display (FPD) such as a liquid crystal display (LCD) or a plasma display panel (PDP). Furthermore, the shape and size of the substrate 1 are not limited by the drawings, and the substrate 1 may have substantially various shapes and sizes such as a circular or rectangular plate.

The substrate processing apparatus 10 includes a housing 11 that forms the exterior of the substrate processing apparatus 10 and the opening and shutting device that opens and closes an entrance 112 formed in the housing 11 for entrance or exit of the substrate 1. The opening and shutting device includes the opening and shutting part 13 that opens and closes the entrance 112 and a drive part 14 that drives the opening and shutting part 13.

The housing 11 includes a chamber block 121 having a processing chamber 12 formed therein in which processing of the substrate 1 is performed and an entrance block 111 having the entrance 112 formed therein. The entrance block 111 may be provided on one side of the chamber block 121 and may be integrally formed, or coupled, with the chamber block 121. For convenience of description, the chamber block 121 and the entrance block 111 are distinguished from each other, but the invention is not limited thereto.

The processing chamber 12 provides a space in which the substrate 1 is received and in which a predetermined processing process, for example, a process including a plasma etching process is performed on the substrate 1. The processing chamber 12 is formed to correspond to the shape of the substrate 1 and is formed as a space that is isolated from the outside except for the entrance 112.

A chuck (not illustrated) on which the substrate 1 is placed or electrodes (not illustrated) for generating plasma may be provided in the processing chamber 12 depending on the type of processing process that is performed in the processing chamber 12.

The entrance 112 has an opening or slit shape that is formed through the entrance block 111 to connect the outside and the processing chamber 12. The entrance 112 has a size corresponding to the diameter and thickness of the substrate 1. Furthermore, the entrance 112 may be formed in a shape having a large width and a small height such that the substrate 1 in the horizontal position is able to be carried through the entrance 112.

Hereinafter, for convenience of description, the direction of a long side of the entrance 112, that is, the direction of a side of the entrance 112 that corresponds to the diameter of the substrate 1 is referred to as the “lengthwise direction”, and the direction of a short side of the entrance 112, that is, the direction of a side of the entrance 112 that corresponds to the thickness of the substrate 1 is referred to as the “height direction”.

The opening and shutting part 13 may be provided in the housing 11. The opening and shutting part 13 may be disposed in the space between the entrance 112 and the processing chamber 12. For example, the opening and shutting part 13 may be provided at the boundary between the chamber block 121 and the entrance block 111 in the housing 11. The opening and shutting part 13 may open and close the entrance 112 while rotating. For example, the opening and shutting part 13 may be selectively brought into close contact with the entrance 112 depending on rotation.

The opening and shutting part 13 may include a rotary member 132 and a door member 131.

The rotary member 132 may rotate about a rotary shaft thereof. The rotary shaft of the rotary member 132 may be parallel to the lengthwise direction of the entrance 112. The rotary member 132 may be provided on a lower side of the entrance 112 so as to be parallel to the lengthwise direction of the entrance 112. However, this embodiment is not limited by the drawings, and the rotary member 132 may be located on an upper side of the entrance 112.

The door member 131 may be connected to the rotary member 132 and may open and close the entrance 112 by operation of the rotary member 132. The door member 131 may have a plate shape that extends from one side on the periphery of the rotary member 132 to the outside in the diameter direction. The door member 131 may include a surface 131a that covers the entrance 112 when the door member 131 closes the entrance 112. Hereinafter, for convenience of description, the surface 131a that covers the entrance 112 is referred to as the “sealing surface”, and the opposite surface of the door member 131 that is opposite to the sealing surface is referred to as the “rear surface”.

The door member 131 may have a plate shape that has an area larger than the open area of the entrance 112 and has, for example, a predetermined thickness. However, the shape of the door member 131 is not limited by the drawings.

With respect to a section perpendicular to the rotary shaft, that is, with respect to FIG. 2, the rotary member 132 may have a circular cross-sectional shape, and the door member 131 may have a shape protruding from the outer surface of the rotary member 132 in the diameter direction. In this case, the sealing surface 131a of the door member 131 may have a shape that extends along the direction of a tangent to the outer surface of the rotary member 132.

In accordance with this structure, when the door member 131 closes the entrance 112 depending on rotation of the rotary member 132, the door member 131 may be brought into close contact with the entrance 112 such that the entire sealing surface 131a covers the entrance 112.

Furthermore, because the rotary member 132 is installed along the lengthwise direction of the door member 131, the length by which the door member 131 protrudes into the processing chamber 12 may be decreased when the door member 131 opens the entrance 112. In addition, a space required for rotation of the door member 131 may be reduced, and the substrate 1 and the door member 131 may be prevented from interfering with each other in the processing chamber 12 in a state in which the door member 131 is rotated to open the entrance 112.

A sealing member 133 may be provided on the sealing surface 131a of the door member 131. When the door member 131 closes the entrance 112, the sealing member 133 is brought into close contact with the entrance 112 and the surrounding surface thereof, thereby more firmly sealing the entrance 112. Furthermore, the sealing member 133 may have a plate shape that is larger than the open area of the entrance 112 and has a predetermined thickness. However, the shape and size of the sealing member 133 are not limited by the drawings.

The drive part 14 may be connected with the rotary shaft of the rotary member 132 and may rotate the rotary member 132. For example, the drive part 14 may be provided outside the housing 11 and connected with the rotary member 132 through the housing 11 and may allow the door member 131 to pivot so as to open and close the entrance 112.

According to this embodiment, the door member 131 may be provided between the entrance 112 and the processing chamber 12 and may seal, in the housing 11, the entrance 112, thereby improving the capability of sealing the entrance 112 and the processing chamber 12. Furthermore, when the door member 131 closes the entrance 112, the sealing force of the door member 131 may be further improved due to the pressure in the processing chamber 12. That is, because the opening and shutting part 13 is provided in the housing 11, when the pressure in the housing 11 is increased, the opening and shutting part 13 may be pressed toward the entrance 112 to perform a function of firmly maintaining the state in which the interior of the housing 11 is sealed.

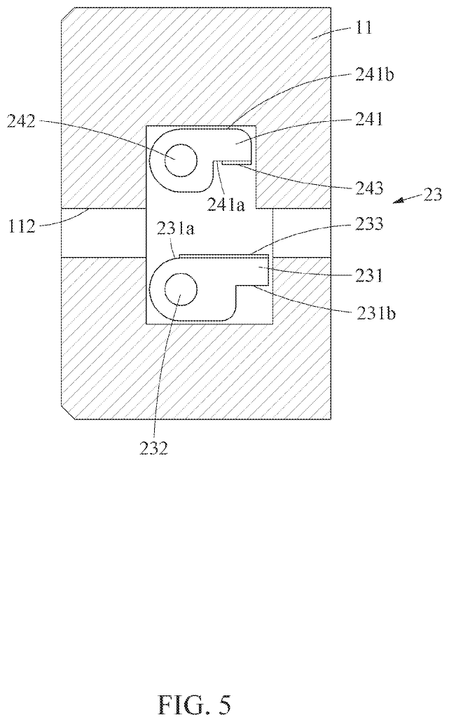

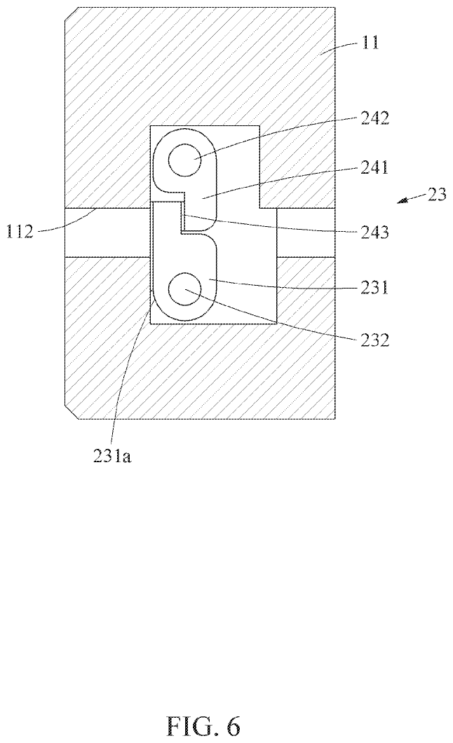

FIG. 5 is a cross-sectional view of an opening and shutting device according to an embodiment. FIG. 6 is a cross-sectional view of the opening and shutting device according to an embodiment.

Referring to FIGS. 5 and 6, a substrate processing apparatus according to an embodiment may include a pair of opening and shutting parts that overlap each other to close an entrance 112. Hereinafter, for convenience of description, the opening and shutting part located on a lower side of the entrance 112 is referred to as the “opening and shutting part” 23, and the opening and shutting part located on an upper side of the entrance 112 is referred to as the “auxiliary opening and shutting part”.

The opening and shutting part 23 may be disposed in a housing 11 so as to be located between a processing chamber 12 and the entrance 112. The opening and shutting part 23 may selectively open and close the entrance 112 while rotating. The opening and shutting part 23 may include a rotary member 232 that rotates about a rotary shaft thereof and a door member 231.

The rotary member 232 may rotate about the rotary shaft thereof. The rotary shaft may be parallel to the lengthwise direction of the entrance 112. The door member 231 may be connected to the rotary member 232 and may cover and close the entrance 112 depending on the rotation of the rotary member 232. The door member 231 may include a surface 231a that is brought into contact with the inner surface of the housing 11 in which the entrance 112 is formed.

A first sealing member 233 may be provided on the surface of the door member 231 (hereinafter, referred to as the “sealing surface” 231a) that corresponds to the entrance 112. When the door member 231 closes the entrance 112, the first sealing member 233 may be brought into close contact with the entrance 112 and the surrounding surface thereof, thereby more firmly sealing the entrance 112. Furthermore, the first sealing member 233 may have a plate shape that has an area larger than the open area of the entrance 112 and has a predetermined thickness. However, the size and shape of the first sealing member 233 are not limited by the drawings.

The auxiliary opening and shutting part may be disposed in the housing 11 so as to be located between the processing chamber 12 and the entrance 112. The auxiliary opening and shutting part may assist with the opening and closing operation of the opening and shutting part 23 while rotating to seal the entrance 112. The auxiliary opening and shutting part may include an auxiliary rotary member 242 and an auxiliary door member 241.

The auxiliary rotary member 242 may rotate about an auxiliary rotary shaft thereof. The auxiliary rotary shaft may be parallel to the lengthwise direction of the entrance 112. The auxiliary door member 241 may be connected to the auxiliary rotary member 242 and may be brought into contact with a rear surface 231b of the door member 231 depending on the rotation of the auxiliary rotary member 242. The auxiliary door member 241 may include a contact surface 241a that is brought into contact with the door member 231.

The door member 231 and the auxiliary door member 241 may have plate shapes that are larger than the open area of the entrance 112 and have predetermined thicknesses. However, the shapes and sizes of the door member 231 and the auxiliary door member 241 are not limited by the drawings as long as the door member 231 and the auxiliary door member 241 have shapes capable of entirely sealing the entrance 112.

In a state in which the door member 231 is rotated to cover the entrance 112, the auxiliary door member 241 may rotate to overlap the rear surface 231b of the door member 231. In the state in which the opening and shutting part 23 and the auxiliary opening and shutting part are operated to close the entrance 112, the contact surface 241a of the auxiliary door member 241 may overlap the rear surface 231b of the door member 231.

In this case, a second sealing member 243 may be formed on the contact surface 241a of the auxiliary door member 241. For example, the second sealing member 243 may be formed in a plate shape that has a size corresponding to the area by which the contact surface 241a of the auxiliary door member 241 overlaps the rear surface 231b of the door member 231, and a predetermined thickness. However, the shape and size of the second sealing member 243 are also not limited by the drawings.

According to this embodiment, the opening and shutting part 23 and the auxiliary opening and shutting part, which are paired together, may overlap each other to seal the entrance 112, thereby improving the capability of sealing the entrance 112 and the processing chamber 12. Furthermore, the pair of door members 231 and 241 provided in the housing 11 may exclude an effect by the interior space of the entrance 112, thereby preventing non-uniformity of plasma density in the processing chamber 12 and non-uniformity of substrate processing caused thereby.

In particular, because the opening and shutting part 23 and the auxiliary opening and shutting part are provided in the housing 11, when the pressure in the housing 11 is increased, the opening and shutting part 23 and the auxiliary opening and shutting part may be pressed toward the entrance 112 to perform a function of firmly maintaining the state in which the interior of the housing 11 is sealed.

As described above, according to this embodiment, the door member opens and closes, in the housing, the entrance, thereby preventing non-uniformity of the interior space of the processing chamber and non-uniformity of plasma density caused thereby and thus enabling a substrate to be uniformly processed.

Furthermore, the sealing member is provided on the door member to improve a sealing effect for entrance and exit.

In addition, the two door members overlap each other to open and close the entrance, thereby improving an effect of sealing the entrance and the processing chamber.

Effects of the substrate processing apparatus according to the embodiment are not limited to the aforementioned effects, and any other effects not mentioned herein will be clearly understood from the following description by those skilled in the art to which the invention pertains.

While the embodiments have been described above with reference to the limited drawings, it will be understood by those skilled in the art that various modifications and alterations can be made without departing from the spirit and scope of the invention described in the specification. For example, suitable results may be achieved even if the described techniques are performed in a different order, and/or the components of the described structure and apparatus are coupled or combined in a different manner or replaced or supplemented by other components or their equivalents.

What is claimed is:

1. A device for opening and closing an entrance through which a substrate is carried into and out of a processing chamber, the device comprising:
an opening and shutting part disposed between the entrance and the processing chamber and configured to open and close the entrance while rotating so as to be brought into close contact with the entrance.

2. The device of claim 1, wherein the opening and shutting part comprises:
a rotary member configured to rotate about a rotary shaft thereof; and
a door member connected to the rotary member, the door member including a sealing surface configured to cover and seal the entrance depending on the rotation of the rotary member.

3. The device of claim 2, wherein the rotary shaft of the rotary member is parallel to a lengthwise direction of the entrance.

4. The device of claim 2, wherein with respect to a section perpendicular to the rotary shaft, the rotary member has a circular cross-sectional shape, and the door member has a shape protruding from an outer surface of the rotary member.

5. The device of claim 4, wherein the door member is formed such that the sealing surface extends along a direction of a tangent to the outer surface of the rotary member.

6. The device of claim 2, wherein the opening and shutting part further comprises:
a sealing member disposed on the sealing surface of the door member configured to cover the entrance.

7. The device of claim 6, wherein the sealing member has a plate shape having a larger area than the entrance.

8. The device of claim 2, further comprising:
a drive part connected with the rotary shaft of the rotary member and configured to rotate the rotary member.

9. An apparatus for processing a substrate, the apparatus comprising:
a housing including a processing chamber for substrate processing and having, on one side thereof, an entrance through which the substrate is carried into and out of the processing chamber;
an opening and shutting part provided in the housing so as to be located between the processing chamber and the entrance, the opening and shutting part being configured to selectively open and close the entrance while rotating; and
a drive part connected with the opening and shutting part and configured to rotate the opening and shutting part.

10. The apparatus of claim 9, wherein the opening and shutting part comprises:
a rotary member configured to rotate about a rotary shaft thereof; and
a door member connected to the rotary member, the door member including a sealing surface configured to be brought into contact with an inner surface of the housing in which the entrance is formed, depending on the rotation of the rotary member.

11. The apparatus of claim 10, further comprising:
an auxiliary opening and shutting part provided in the housing so as to be located between the processing chamber and the entrance, the auxiliary opening and shutting part being configured to rotate to seal the entrance.

12. The apparatus of claim 11, wherein the auxiliary opening and shutting part comprises:
an auxiliary rotary member configured to rotate about an auxiliary rotary shaft thereof; and
an auxiliary door member connected to the auxiliary rotary member, the auxiliary door member including a contact surface configured to be brought into contact with the door member.

13. The apparatus of claim 12, wherein the auxiliary door member rotates to overlap the door member in a state in which the door member is rotated to cover the entrance.

14. The apparatus of claim 12, wherein the rotary shaft and the auxiliary rotary shaft are parallel to a lengthwise direction of the entrance.

15. The apparatus of claim 14, wherein the rotary shaft and the auxiliary rotary shaft are located to be vertically symmetric to each other with respect to the entrance.

16. The apparatus of claim 12, wherein the contact surface of the auxiliary door member has an area corresponding to an area of a rear surface of the door member that is opposite to the sealing surface of the door member.

17. The apparatus of claim 12, wherein the auxiliary opening and shutting part further comprises a sealing member provided on the contact surface.
